(19) United States
(12) Patent Application Publication
(10) Pub. No.: US 2019/0190607 A1
(43) Pub. Date: Jun. 20, 2019

(54) SMALL FORM FACTOR HOT PLUGGABLE TRANSCEIVER MODULE

(71) Applicant: OptoMedia Technology Inc., Hsinchu County (TW)

(72) Inventors: Hui-Tsuo Chou, Hsinchu County (TW); Ching-Wei Chiu, Hsinchu County (TW); Pei-Hsiang Hsu, Hsinchu County (TW)

(21) Appl. No.: 16/220,298

(22) Filed: Dec. 14, 2018

Related U.S. Application Data
(60) Provisional application No. 62/599,863, filed on Dec. 18, 2017.

(51) Int. Cl. H04B 10/40; H04B 1/38; G02B 6/42; H05K 1/11

(52) U.S. Cl. CPC H04B 10/40; H04B 1/38; H05K 2201/10121; G02B 6/428; H05K 1/117; G02B 6/4246

(57) ABSTRACT

The invention provides a small form factor pluggable transceiver module comprising a housing, a transmission line and at least one connector, wherein the frond surface of the housing has a connecting hole, and the housing is dimensioned according to a SFP [symbol] SFP+ [symbol] XFP [symbol] Xenpak [symbol] QSFP [symbol] QSFP+ [symbol] CFP or CPAK. One end of the transmission line is disposed in the connecting hole on the front surface of the housing, and the other end of the transmission line is connected to a connector, so that the small form factor pluggable transceiver module can be disposed a larger number of connectors.

### REFERENCE TO RELATED APPLICATIONS

This Application is based on Provisional Patent Application Ser. No. 62/599,863, filed 18 Dec. 2017, currently pending.

### FIELD OF THE INVENTION

The present invention relates to a small form factor pluggable transceiver module that is able to be disposed a larger number of connectors.

### BACKGROUND

Optical communication is communication technology that uses light to carry information. Among them, fiber optic communication is the most commonly used optical communication technology. Fiber optic communication is a method of transmitting information from one place to another by sending pulses of light through an optical fiber. Fiber is preferred over electrical cabling when high bandwidth, long distance, or immunity to electromagnetic interference are required.

In the field of optical communications, the transceiver is an important component, such as Gigabit Interface Converter (GBIC). The transceiver is mainly disposed on a host device, and includes an optical transmitter and an optical receiver. The optical transmitter converts electrical signals into optical signals and transmits the optical signals through the optical fiber, and the optical receiver is used to convert the received optical signals into electrical signals, and transmit the electrical signals to the host device.

Recently, the gigabit interface converter (GBIC) has been gradually replaced by a small form factor transceiver (SFF transceiver), and further improved into a small form-factor pluggable transceiver (SFP). The small form-factor pluggable transceiver is not only small in size, but also supports hot plugging, which not only reduces the space for installation, but also improves the convenience of replacement and installation of the optical transceiver.

### SUMMARY

An object of the present invention is to provide a small form factor pluggable transceiver module comprising a housing, a transmission line and a plurality of connectors, wherein the connectors are connected to the front surface of the housing via the transmission line. Further, the housing of the small form factor pluggable transceiver module is dimensioned according to a SFP [symbol] SFP+ [symbol] XFP [symbol] Xenpak [symbol] QSFP [symbol] QSFP+ [symbol] CFP or CPAK. The housing is able to be disposed on the host device, so that the host device has a larger number of connectors by disposing a single small form factor pluggable transceiver module, thereby improving the convenience in use.

Another object of the present invention is to provide a small form factor pluggable transceiver module comprising a housing, a transmission line and at least one connector, wherein the connector is connected to the front surface of the housing via the transmission line. The cross-sectional area of the transmission line is smaller than the cross-sectional area of the connector, so that the small form factor pluggable transceiver module can dispose a larger number of connectors by disposing the transmission line.

Another object of the present invention is to provide a small form factor pluggable transceiver module. A transmission line is disposed on the front surface of the housing, and comprises a main transmission line and a plurality of sub transmission lines. One end the sub transmission lines are connected to the front surface of the housing via the main transmission line, and the other end of the sub transmission lines are respectively connected to a connector, so that the small form factor pluggable transceiver module can dispose a larger number of connectors.

According to an embodiment of the present invention, a small form factor pluggable transceiver module, comprises: a housing for inserting into a host device, wherein said housing being dimensioned according to a SFP, SFP+, XFP, Xenpak, QSFP, QSFP+, CFP or CPAK; at least one connecting hole located on a front surface of said housing; at least one transmission line, wherein one end of said transmission line is disposed in said connecting hole; and at least one connector located the other end of said transmission line.

### BRIEF DESCRIPTION OF THE DRAWINGS

The structure as well as preferred modes of use, further objects, and advantages of this invention will be best understood by referring to the following detailed description of some illustrative embodiments in conjunction with the accompanying drawings, in which:

FIG. 1 is a top perspective view of a small form factor pluggable transceiver module according to an embodiment of the invention.

FIG. 2 is a bottom perspective view of a small form factor pluggable transceiver module according to an embodiment of the invention.

FIG. 3 is a top perspective view of a small form factor pluggable transceiver module according to another embodiment of the invention.

FIG. 4 is a top perspective view of a small form factor pluggable transceiver module according to another embodiment of the invention.

FIG. 5 is a top perspective view of a small form factor pluggable transceiver module according to another embodiment of the invention.

FIG. 6 is a top perspective view of a small form factor pluggable transceiver module according to another embodiment of the invention.

FIG. 7 is a top perspective view of a small form factor pluggable transceiver module according to another embodiment of the invention.

FIG. 8 is a top perspective view of a small form factor pluggable transceiver module according to another embodiment of the invention.

FIG. 9 is a block diagram of a small form factor pluggable transceiver module according to an embodiment of the invention.

### DETAILED DESCRIPTION OF THE PREFERRED EMBODIMENTS

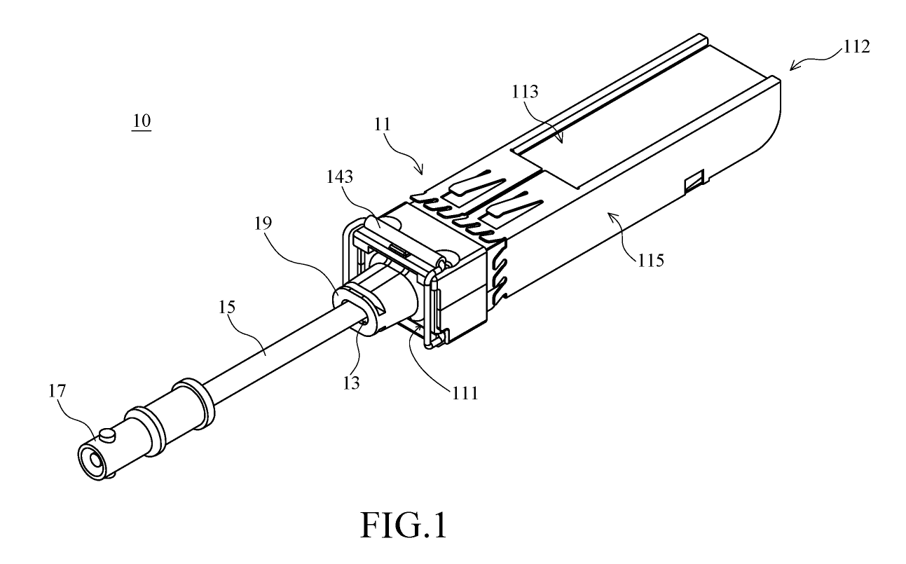

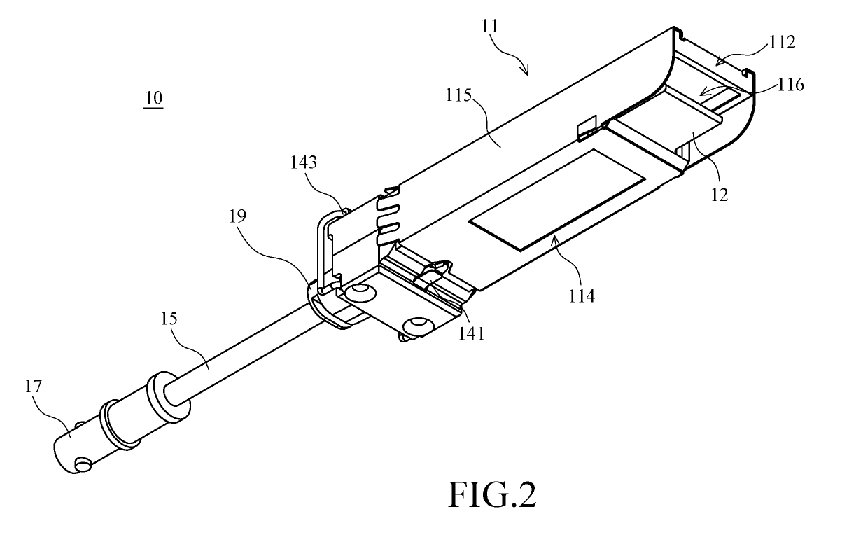

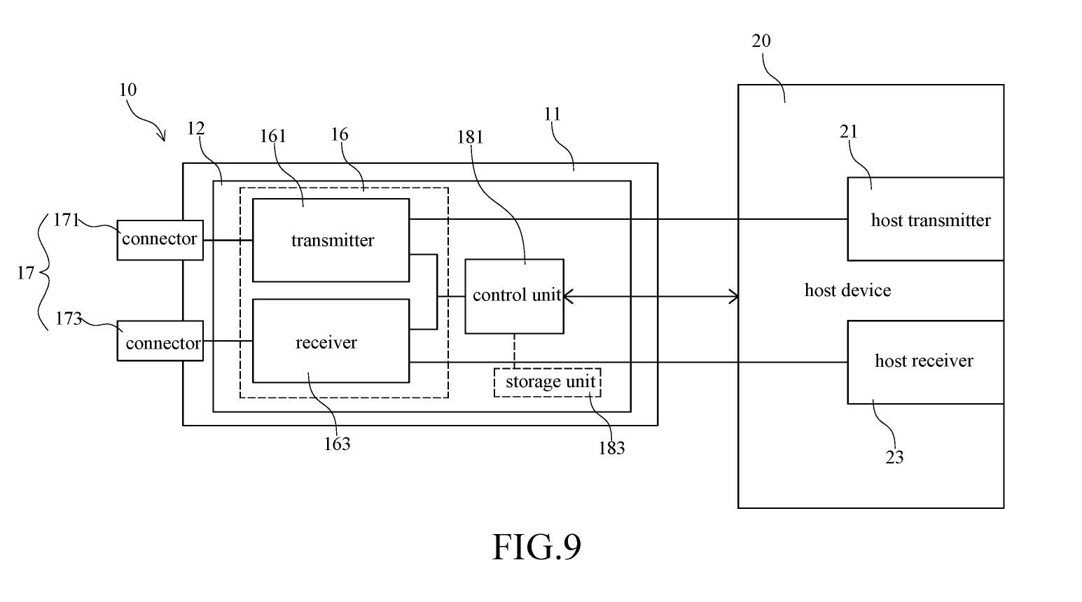

FIG. 1 and FIG. 2 are respectively a top and bottom perspective views of a small form factor pluggable transceiver module according to an embodiment of the invention. The small form factor pluggable transceiver module 10 comprises a housing 11, a connecting hole 13, a transmission line 15 and a connector 7, wherein the housing 11 is able to be inserted into a host device 20, such as a computer, a network switch or a router, as shown in FIG. 9. Further, the housing 11 is dimensioned according to a SFP (Small Form-factor Pluggable transceiver), SFP+ (Enhance Small Form-factor Pluggable transceiver), XFP (10 Gigabit Small Form-factor Pluggable transceiver), Xenpak, QSFP (Quad Small Form-factor Pluggable), QSFP+ (Quad Small Form-factor Pluggable), CFP or CPAK.

In one embodiment of the invention, the housing 11 may be a cuboid, and includes a front surface 111, a rear surface 112, a top surface 113, a bottom surface 114 and two side surfaces 115, wherein a connecting hole 13 is disposed on the front surface 111. For example, housing 11 is dimensioned according to a SFP (Small Form-factor Pluggable transceiver), wherein the front surface 111 of the housing 11 has a height of about 10.5 mm, the front surface 111 has a width of about 13.9 mm, the rear surface 112 of the housing 11 has a height of about 8.5 mm, the rear surface 112 of the housing 11 has a width of about 13.4 mm, and the housing 11 has a length of about 57.5 mm. The above dimensions are only a specific embodiment of the invention and are not limitation of the invention.

The transmission line 15 has two ends, wherein one end of the transmission line 15 is located within the connecting hole 13 on the front surface 111 of the housing 11, and the other end of the transmission line 15 is connected to a connector 17. The transmission line 15 may be a flexible transmission line, and can be used to transmit optical signals or electrical signals. For example, the transmission line 15 can be a coaxial cable or an optical fiber.

In particular, the small form factor pluggable transceiver module 10 is relatively small in size, such that the number and location of connectors 17 that are disposed on the small form factor pluggable transceiver module 10 may be limited. For example, the front surface 111 of the housing 11 of the small form factor pluggable transceiver module 10 can only be directly provided with one connector 17. If two connectors 17 are directly provided on the front surface 111 of the housing 11, the two connectors 17 have to be disposed on the diagonal of the front surface 111.

Further, it is impossible to provide more connectors 17 on the front surface 111 of the housing 11, after the two connectors 17 are disposed on the front surface 111 of the housing 11. Unless the area of the front surface 111 of the housing 11 is increased. However, it will result in the housing 11 being fail to conform to the dimensions of the SFP, SFP+, XFP, Xenpak, QSFP, QSFP+, CFP or CPAK specifications.

In order to solve the above problems, the present invention propose to connect the housing 11 and the connector 17 through the transmission line 15, wherein the cross-sectional area of the transmission line 15 is smaller than the cross-sectional area of the connector 17, so that the small form factor pluggable transceiver module 10 can dispose a larger number of connectors 17 and/or transmission lines 15.

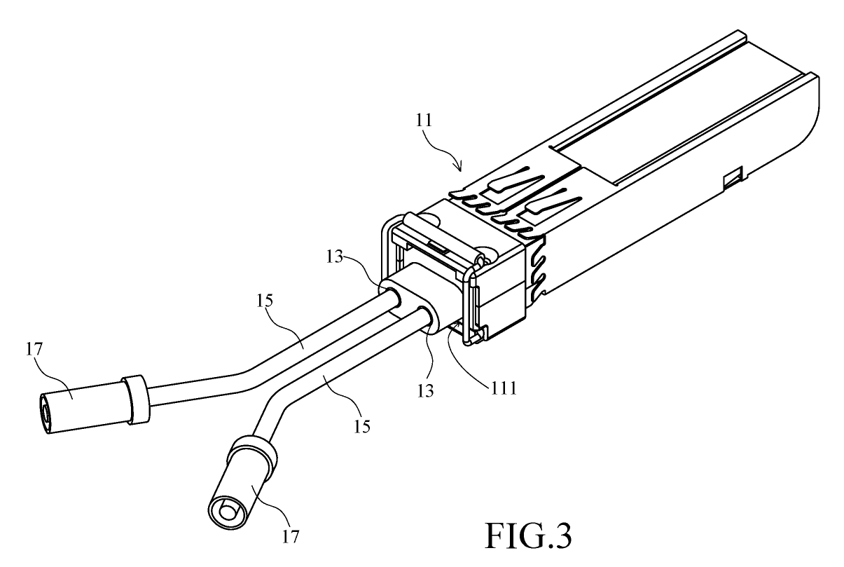

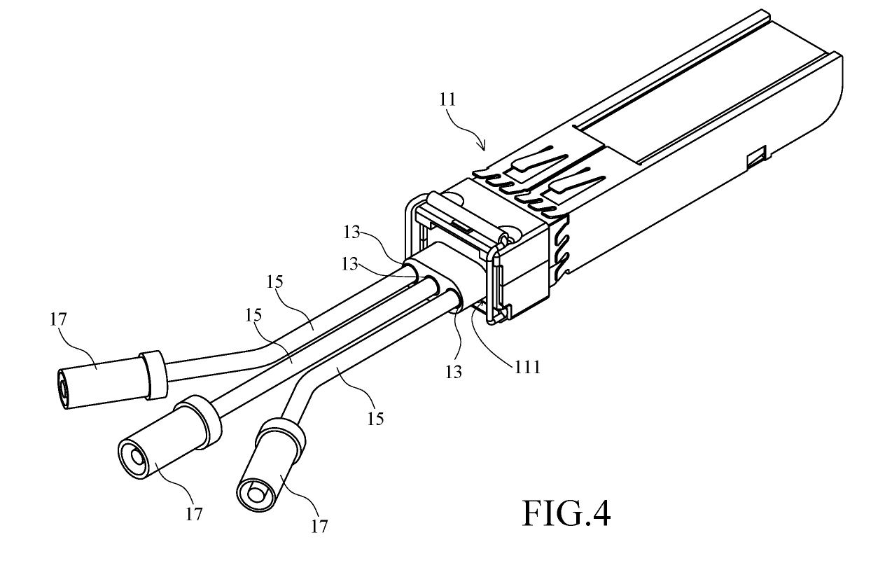

In one embodiment of invention, the small form factor pluggable transceiver module 10 comprises a plurality of transmission lines 15, connectors 17 and connecting holes 13, and one end of each transmission line 15 is respectively disposed in each connecting hole 13. For example, the frond surface 111 of the housing 11 has two connecting holes 13, wherein one end of two transmission lines 15 is respectively located in two connecting holes 13 on the front surface 111 of the housing 11, and the other end of two transmission lines 15 is respectively connected to a connector 17, as shown in FIG. 3. In other embodiment of the invention, the front surface 111 of the housing 11 has three connector holes 13, wherein one end of three transmission lines 15 is respectively located in three connecting holes 13 on the front surface 111 of the housing 11, and the other end of three transmission lines 15 is respectively connected to a connector 17, as shown in FIG. 4.

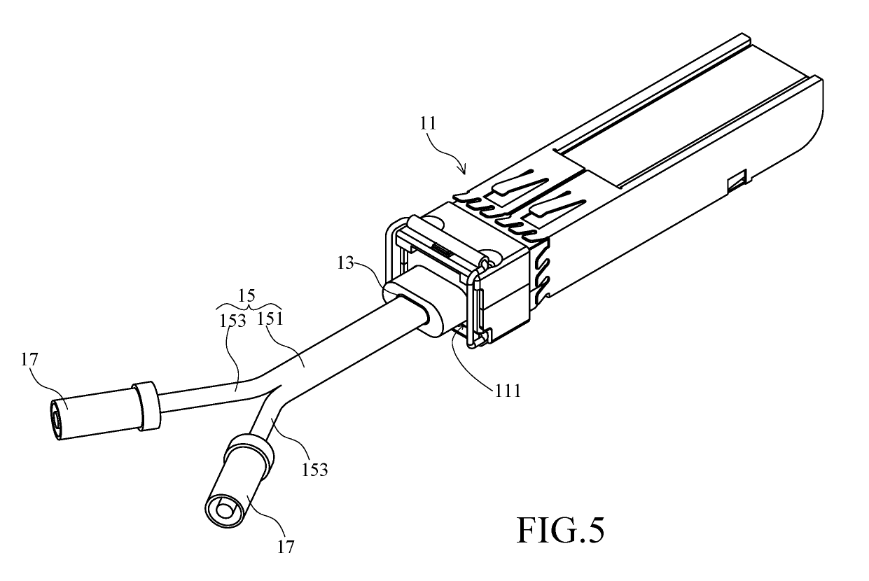

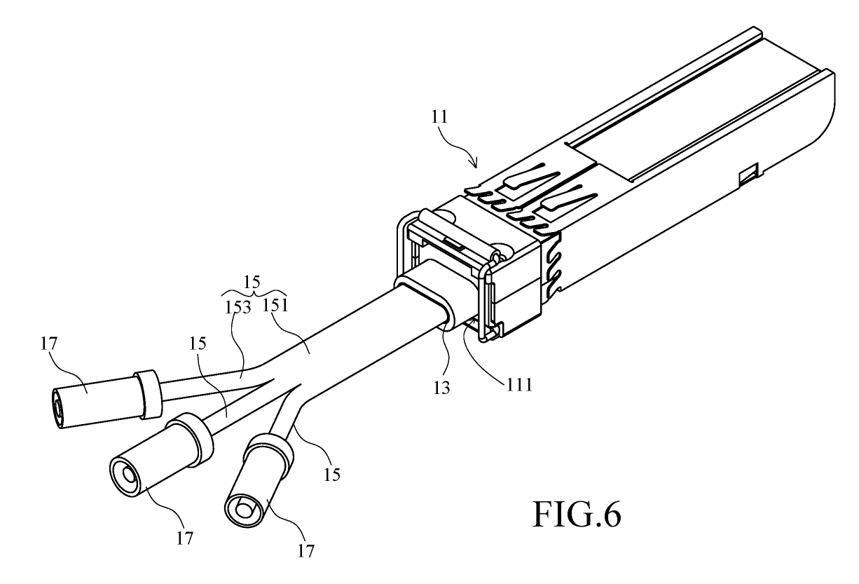

In one embodiment of the invention, the transmission line 15 comprises a main transmission line 151 and a plurality of sub transmission lines 153. The front surface 111 of the housing 11 has a connecting hole 13, wherein one end of the main transmission line 151 is disposed in the connecting hole 13 on the front surface 111 of the housing 11, and the other end of the main transmission line 151 is connected with one end of two sub transmission lines 153. Thus, two sub transmission lines 153 are branches on the main transmission line 151, and the other end of two sub transmission lines 153 is respectively connected to a connector 17, as shown in FIG. 5. In other embodiment of the invention, one end of the main transmission line 151 is disposed in the connecting hole 13 on the front surface 111 of the housing 11. The other end of the main transmission line 151 is connected with one end of three sub transmission lines 153, and the other end of three sub transmission lines 153 is respectively connected a connector 17, as shown in FIG. 6.

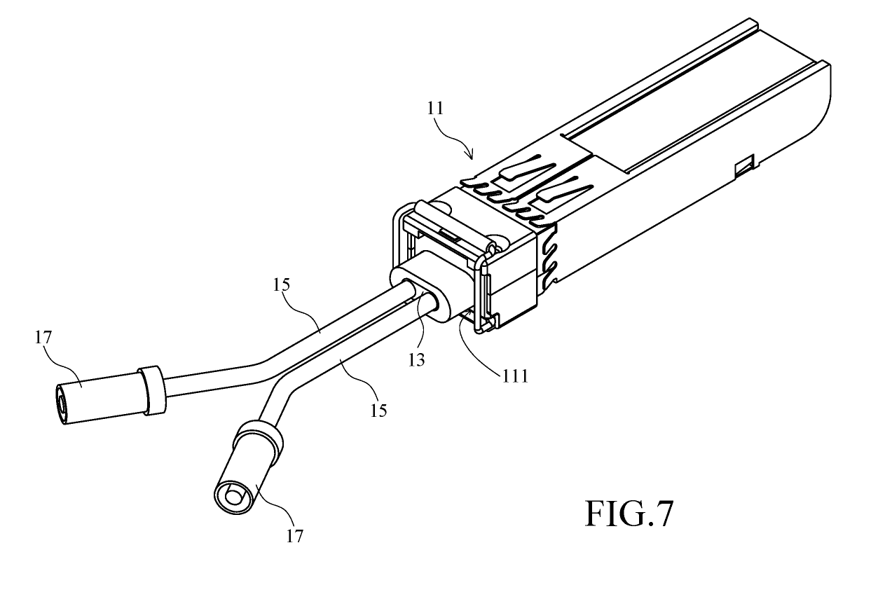

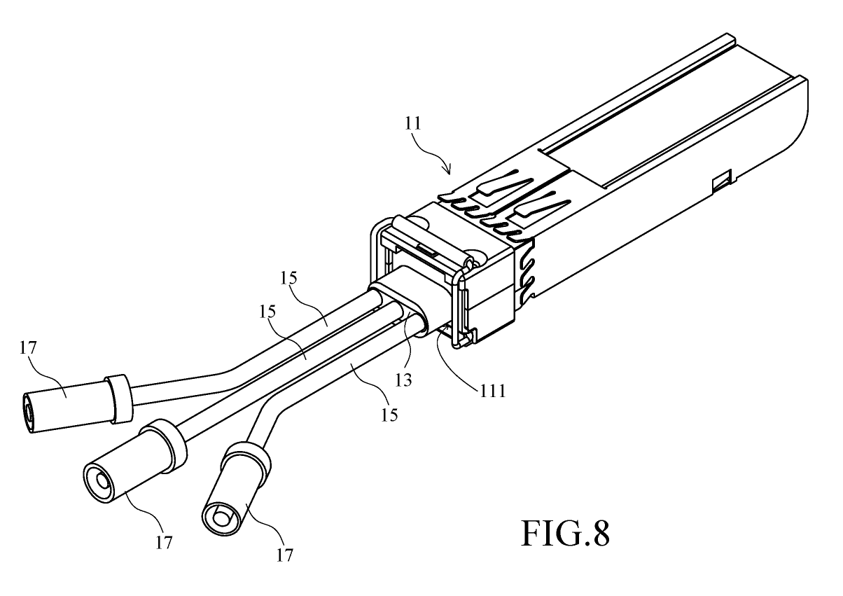

In one embodiment of the invention, the small form factor pluggable transceiver module 10 comprises a plurality of transmission lines 15, a plurality of connectors 17 and a connecting hole 13, and one end of each transmission line 15 is disposed in the same connecting hole 13. For example, the frond surface 111 of the housing 11 has one connecting hole 13, wherein one end of two transmission lines 15 is located in the same connecting hole 13 on the front surface 111 of the housing 11, and the other end of two transmission lines 15 is respectively connected to a connector 17, as shown in FIG. 7. In other embodiment of the invention, one end of three transmission lines 15 is located in the same connecting hole 13 on the front surface 111 of the housing 11, and the other end of three transmission lines 15 is respectively connected to a connector 17, as shown in FIG. 8.

In above embodiments of the present invention, the small form factor pluggable transceiver module 10 has two or three transmission lines 15, two or three connectors 17, and/or two or three sub transmission lines 153. In actual application, the number of the transmission line 15, the connector 17, and/or the sub transmission line 153 may be more than three. Further, each connector 17 may has the same or a different function. For example, a portion of the connectors 17 are capable of transmitting optical signals or electrical signals, while other connectors 17 are capable of receiving optical signals or electrical signals.

In one embodiment of the invention, the front surface 111 of the housing 11 further comprises a connecting seat 19, wherein the connecting hole 13 is located on the connecting seat 19. One end of at least one transmission line 15 or main transmission line 151 is disposed in the connecting hole 13 on the connecting seat 19.

The connector 17 described in the invention is an optical connector for transmitting or receiving optical signals, or an electrical connector for transmitting or receiving electrical signals. For example, the connector 17 is a coaxial cable connector, a DIN connector (Deutsches Institut für Normung, DIN 1.0/2.3), a SMP connector (Sub-Miniature Push-on,), SMB connector (Sub-Miniature version), SMC (Sub-Miniature version C), HD BNC connector, mini BNC connector, F-type connector, SMA connector (Sub-Miniature version A), AFI connector, MCX connector (Micro coaxial connector) or SMPM connector. In addition, each connector 17 may be the connectors with different specifications to increase the connecting interface of the connector 17 of the small form factor pluggable transceiver module 10.

A space 116 is formed within the housing 11, and a PCB (Printed circuit board) 12 is located within the space 116 of the housing 11. The PCB 12 is electrically connected to the transmission line 15, and electrically connected to the connector 17 via the transmission line 15. Further, the PCB 12 located on the rear surface 112 of the housing 11 has a transmission terminal (not shown). When the small form factor pluggable transceiver module 10 is disposed on the host device 20, the transmission terminal of the PCB 12 is electrically connected with the host device 20 for transmitting electrical signal.

A latch 141 is disposed on the surface of the housing 11 to fix the small form factor pluggable transceiver module 10 on the host device 20. In one embedment of the invention, the latch 141 is connected to an actuator 143, and the user is able to operate, such as pull or push, the actuator 143 to drive the latch 141. For example, the latch 141 is located on the bottom surface 114 of the housing 11, and the actuator 143 is located on the top surface 113 of the housing 11.

FIG. 9 is a block diagram of a small form factor pluggable transceiver module according to an embodiment of the invention. The small form factor pluggable transceiver module 10 is able to connect the host device 20, and comprises a housing 11 and a PCB 12. A transmitter 161, a receiver 163, a control unit 181 and/or a storage unit 183 are disposed on the PCB 12, and the housing 11 covers the PCB 12, the transmitter 161, the receiver 163, the control unit 181 and/or the storage unit 183.

In one embodiment of the invention, the transmitter 161 on the PCB 12 is electrically connected to a connector 17, such as a first connector 171, for transmitting signal via the first connector 171, and the receiver 161 is electrically connected to other connector 17, such as a second connector 173, for receiving signal via the second connector 173.

More specifically, the transmitter 161 may be an electrical transmitter or an optical transmitter. In one embodiment, the transmitter 161 is the optical transmitter, and comprises at least one light emitting diode or laser diode. The receiver 163 may be an electrical receiver or an optical receiver. In one embodiment, the receiver 163 is the optical receiver, and comprises at least one photodetector, such as photo diode. The receiver 163 is capable of converting the received optical signal to the electrical signal, and then transmits the electrical signal to the host device 20.

As the small form factor pluggable transceiver module 10 connects with or inserts into the host device 20, the transmitter 161 and the receiver 163 of the small form factor pluggable transceiver module 10 will be electrically connected with the host transmitter 21 and the host receiver 23 of the host device 20 respectively.

In above embodiment of the invention, the transmitter 161 and the receiver 163 are respectively connected to different connectors 17 for transmitting or receiving signal via different connectors 17. In other embodiment of the invention, the transmitter 161 and the receiver 163 may be connected to the same connector 17, and transmits or receives the optical signal or the electrical signal via the same connector 17.

In one embodiment of the invention, the transmitter 161 and the receiver 163 may be integrated into a transceiver 16 that is electrically connected to a plurality of connectors 17, and receives or transmits the optical signal or the electrical signal via different connectors 17 respectively. In other embodiment, transceiver 16 may be connected to the same connector 17, and receives or transmits the optical signal or the electrical signal via the same connector 17.

A control unit 181 is electrically connected to the transmitter 161, the receiver 163 and/or the transceiver 16, and the control unit 181 is able to monitor the amplitude, data transmission rate or clock and data recovery (CDR) operation mode of the received or transmitted signal. For example, the operation mode comprises bypass mode, reclock mode and unlock mode. Further, as the small form factor pluggable transceiver module 10 connects with the host device 20, the control unit 181 is electrically connected to the host device 20, and transmits the monitoring signal to the hose device 20, or receives a control signal from the host device 20.

More specifically, the host device 20 is able to transmit the control signal to the control unit 181 according to the monitoring signal transmitted by the control unit 181, and then the control unit 181 controls the receiver 163 and/or the transceiver 16 to adjust the amplitude, the bandwidth, the pre-emphasis and/or the de-emphasis of the signal, and compensate for the loss of received signals. In addition, the host device 20 can also adjust the transmitted signal of the transmitter 161 through the control unit 181 to improve the quality of the transmitted signal.

In addition, the host device 20 can monitor the amplitude of the received signal or the transmitted signal through the Digital Diagnostic Monitor (DDM) function of the small form factor pluggable transceiver module 10 or the control unit 181.

In one embodiment of the invention, the small form factor pluggable transceiver module 10 may comprise a storage unit 183 for storing parameters, such as quality parameters. The storage unit 183 is electrically connected to the control unit 181, and the host device 20 is able to read or set the parameters stored by the storage unit 183. The control unit 181 monitors the quality parameters, such as EYE OPEN, EYE HIGHT, EYE JITTER, of the transmitted signal and received signal, and stores the quality parameters in the storage unit 183.

The storage unit 183 may storage requirements or instructions transmitted from the host device 20, and the control unit 181 will adjust or set quality parameters according to these requirements or instructions. When the host device 20 is restarted, these requirements or instructions will still be stored in the storage unit 183 of the small form factor pluggable transceiver module 10, and the control unit 181 can read these requirements or instructions from the storage unit 183 to adjust or set quality parameters for improving the loss of transmitted or received signals.

The above disclosures are only the preferred embodiments of the present invention, and are not to be used to limit the scope of the present invention. All equivalent variations and modifications on the basis of shapes, structures, features and spirits described in claims of the present invention should be included in the claims of the present invention.

1. A small form factor pluggable transceiver module, comprising:
a housing for inserting into a host device, wherein said housing being dimensioned according to a SFP, SFP+, XFP, Xenpak, QSFP, QSFP+, CFP or CPAK;
at least one connecting hole located on a front surface of said housing;
at least one transmission line, wherein one end of said transmission line is disposed in said connecting hole; and
at least one connector located the other end of said transmission line.

2. The small form factor pluggable transceiver module of claim 1, comprising a plurality of transmission lines, a plurality of connectors and a connecting hole, wherein one end of each said transmission line is disposed in said connecting hole, and the other end of each said transmission line is respectively connected to each said connector.

3. The small form factor pluggable transceiver module of claim 1, comprising a plurality of transmission lines, a plurality of connectors and a plurality of connecting holes, wherein one end of each said transmission line is respectively disposed in each said connecting hole, and the other end of each said transmission line is respectively connected to each said connector.

4. The small form factor pluggable transceiver module of claim 1, comprising a connecting seat disposed on said front surface of said housing, and said connecting hole disposed on said connecting seat.

5. The small form factor pluggable transceiver module of claim 1, wherein said transmission line comprises a main transmission line and a plurality of sub transmission lines, one end of said main transmission line is disposed in said connecting hole, the other end of said main transmission line is connected to one end of each said sub transmission line, and each said connector is connected to the other end of each said sub transmission lien respectively.

6. The small form factor pluggable transceiver module of claim 1, comprising a latch located on a surface of said housing for fixing said housing to said host device.

7. The small form factor pluggable transceiver module of claim 6, further comprising an actuator connected to said latch for driving said latch.

8. The small form factor pluggable transceiver module of claim 1, comprising a PCB located within a space of said housing, and said PCB electrically connected with said connector via said transmission line.

9. The small form factor pluggable transceiver module of claim 8, comprising a control unit, a receiver and a transmitter located on said PCB, and said control unit electrically connected to said receiver and said transmitter.

10. The small form factor pluggable transceiver module of claim 9, wherein said receiver and said transmitter are integrated into a transceiver.

11. The small form factor pluggable transceiver module of claim 9, comprising a storage unit located on said PCB, and electrically connected to said control unit.

12. The small form factor pluggable transceiver module of claim 9, wherein said receiver and said transmitter are respectively connected to different said connectors, and respectively receive or transmit an optical signal or an electrical signal via different said connectors.

13. The small form factor pluggable transceiver module of claim 1, wherein said control unit, said receiver and said transmitter are electrically connected to said host device.

14. The small form factor pluggable transceiver module of claim 1, wherein a cross-sectional area of said transmission line is smaller than a cross-sectional area of said connector.
